(19) United States
(12) Patent Application Publication
(10) Pub. No.: US 2023/0067712 A1
(43) Pub. Date: Mar. 2, 2023

(54) Multi Color LED Video Tile

(71) Applicant: Production Resource Group, LLC, New Windsor, NY (US)

(72) Inventor: Christopher D. Conti, Rutherford, NJ (US)

(21) Appl. No.: 17/821,689

(22) Filed: Aug. 23, 2022

Related U.S. Application Data
(60) Provisional application No. 63/260,611, filed on Aug. 26, 2021.

(51) Int. Cl. H01L 27/15; G09F 9/302; H04N 5/222

(52) U.S. Cl. CPC H01L 27/156; G09F 9/3026; H04N 5/2224

(57) ABSTRACT

An LED wall system, with a camera for imaging an area that is illuminated by the LED wall system. The LEDs have a plurality of emitting pixels, each emitting pixel formed of at least one LED, the emitting pixels having primary colors, and also having at least one secondary color other than primary color pixels.

This Application Claims priority from Provisional Application No. 63/260,611, filed Aug. 26, 2021, the entire contents of which are herewith incorporated by reference.

### BACKGROUND

LED Video tiles are widely used in the Entertainment Industry to construct video screens of different dimensions and shapes in order to display video signals for an audience.

One particular use case is LED Video tiles are used in the Motion Picture and Television industries to create virtual scenery. This can be used to replace real scenery or green screens, and also can be a replacement for being on location.

### SUMMARY

One by-product of using LED screens for virtual scenery in Motion Picture and Television applications is that the spectrum of light that the screens emit is limited.

The inventor believes this is due to the fact that, currently, LED screens are made up of only Red, Green, Blue pixels. FIG. 9 shows how when these kinds of LED screens 900 are used as a background, the background is actually formed of columns of red, green and blue pixels 905.

Modern television and cinema cameras now have sensors that can detect and capture a wider spectrum of light than ever before. As a result, video signals can now be transmitted to LED screens that contain values for colors other than Red, Green, and Blue.

### BRIEF DESCRIPTION OF THE DRAWINGS

the drawings show aspects of the invention, and specifically,

FIG. 1 shows an LED wall formed of pixels, having only red green and blue portions to each pixel;

FIG. 2 shows a LED wall formed of multiple pixel parts, each pixel part being a separate color;

FIG. 3 shows an LED wall formed of multiple tricolor pixels, where each two adjacent pixels are of different configurations;

FIG. 4 shows an LED wall formed of multiple pixels each pixel having six colors;

FIG. 5A shows a specific RGGB pixel;

FIG. 5B shows a different specific RGGB pixel;

FIG. 6A shows a pixel including emerald;

FIG. 6B shows a pixel including dual yellows;

FIG. 6C shows a pixel including white;

FIG. 6D shows a pixel including lime;

FIG. 6E shows a six color pixel including Amber, white and lime;

FIG. 6F shows a six color pixel including cyan, magenta and yellow;

FIG. 7A shows a pixel including dual yellows;

FIG. 7B shows a pixel including white;

FIG. 7C shows a pixel including cyan yellow magenta and green;

FIG. 8 shows a color pixel including cyan magenta yellow Amber white;

FIG. 9 shows a backdrop formed of RGB pixels;

FIG. 10 shows a scene including LED walls; and

FIG. 11 shows an area with virtual scenery.

### DETAILED DESCRIPTION

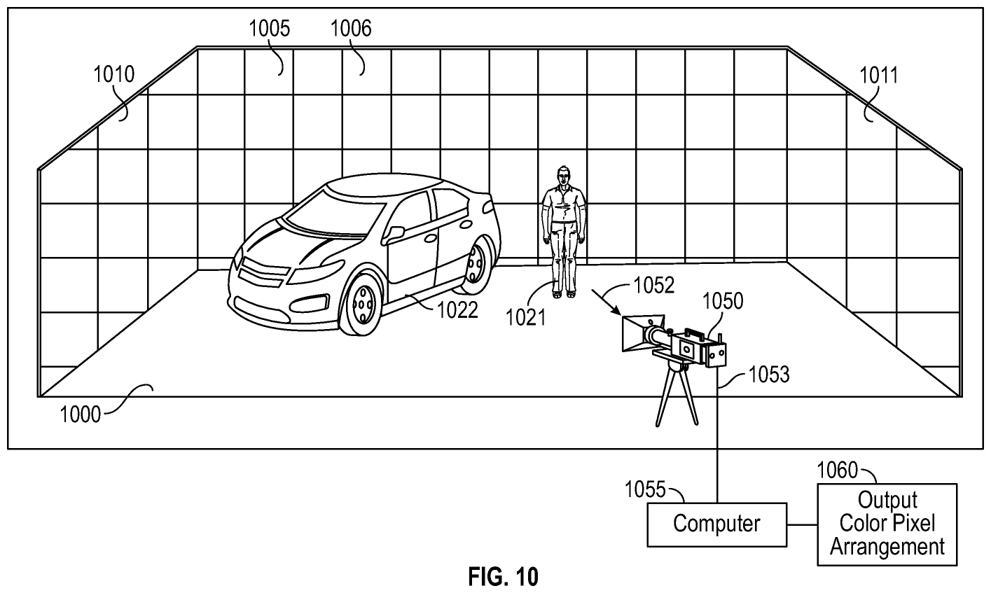

In this application, multiple video screens are used as a back drop, side drop, and/or in other planes and angles, including overhead, underfoot (on/as the floor), as shown in FIG. 10. The system is set up with LED walls 1000 on the floor, LED walls 1005 on the rear, and LED walls 1010 and 1011 on the two sides. Each LED wall such as 1005 includes individual LED tiles such as 1006 located next to one another and each configured with a color palette of the type described herein.

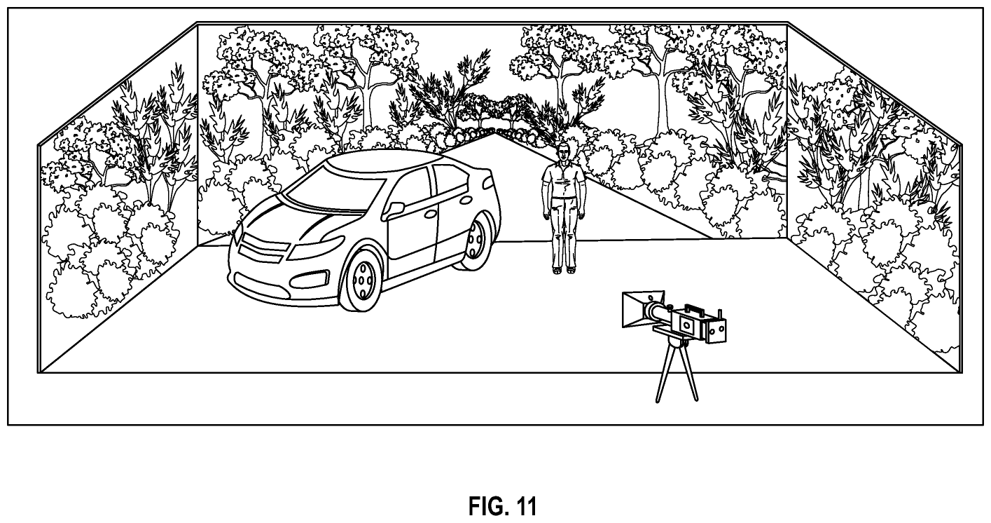

Once set up, video content is played back on the screens that simulates a particular location as shown in FIG. 11.

There are multiple advantages to this type of setup. These systems have the ability to simulate any kind of scene, including an outdoor scene, while remaining in a studio location. This enables operation in the studio as opposed to a remote location. Another advantage is that the LED screens, by their nature, generate light. This light illuminates the actors and set pieces, that may be placed on the stage in front of the screens, in such a way that the scene mimics being on location.

This is accomplished by the fact that the LED screens emit light and create highlights, shadows, colors, and reflections that would normally be found on location. The advantage of this is that the recording camera captures all of this and as a result reduces or even eliminates the need for post-production editing where highlights, shadows, colors, and reflections would have to be created and added after the fact.

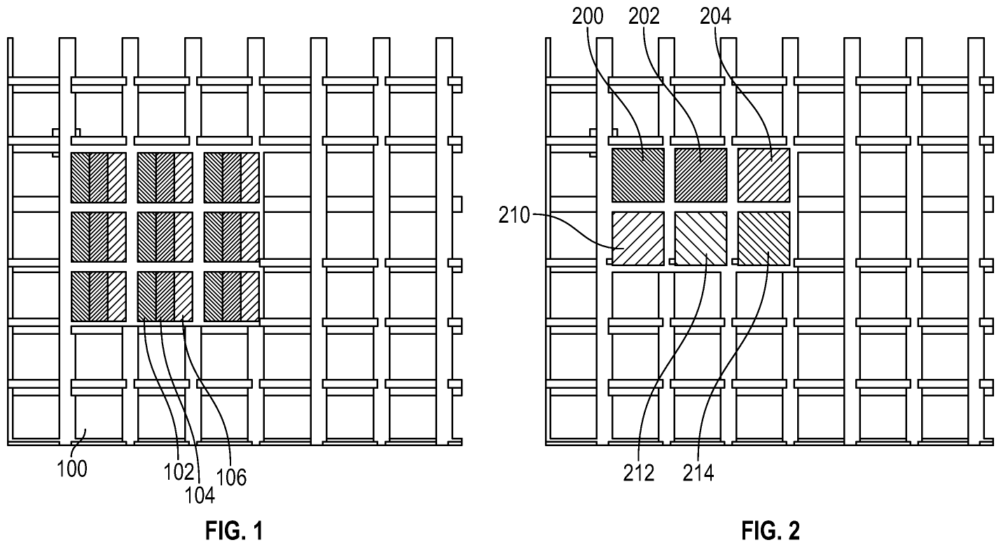

FIG. 1. shows a standard video display tile with pixels 100, each pixel made up of a single chip that contains only red 102, green 104, and blue 106 portions.

According to embodiments, each pixel may have multiple different colors that are emitted. Each of these multiple different colors can be referred to as an LED or LED part. The pixel can have separate LEDs for each color, or can have a singular LED which can emit multiple colors in its different parts.

In one embodiment, the extra color is set according to the needs of the system. In one embodiment, the specific sensitivity of the camera is characterized relative to the output amount of the different chips. For example, a camera whose output would be improved by additional to amber light may be characterized, and then an LED wall is used that has extra amber chips. In another embodiment, either artificial intelligence, or a computer, is used to characterize the light which is received by the camera to determine if that light should be modified in color for any reason, and the LED chips which are used have parts which are set to modify the color as determined by that analysis.

In another embodiment, the output of the camera is characterized, and determined that each pixel should have multiple different colors, such as multiples of the primary colors which can be red green and blue. In another embodiment, the output of the camera is characterized and a determination is made that additional output of one of the primary colors, for example red, would improve the picture. In this case, the pixel can be output with a single additional color, such as red green blue red for each pixel.

FIG. 10 shows the camera 1050, receiving an image 1052, which can be received from the walls on the sides 1010, 1011, the back walls, 1005, reflected off of the items in the picture including the person 1021 and the car 1022 although these are exemplary and of course any items can be in the picture. The output 1053 of the camera is sent to a computer 1055 which characterizes this output according to either desired characteristics, or according to a preset criteria. Based on the analysis, the computer determines the arrangement that each of the color pixels in the LED walls should have. This can be different color pixel arrangements for the sidewalls and bottom walls and back walls, or can be all the same color pixel arrangements. The color pixel arrangements can be any of the color pixel arrangements described herein.

FIG. 2 shows a video display tile with pixels made up of single color LEDs. In this embodiment, there are more colors of LEDs, including red 200, green 202, and blue 204. There are also secondary pixels with other colors including cyan 210, magenta 212 and yellow 214. The resulting LED video display tile has single color pixels made up of multiple individual colors Red, Green, Blue; Cyan, Magenta, and Yellow

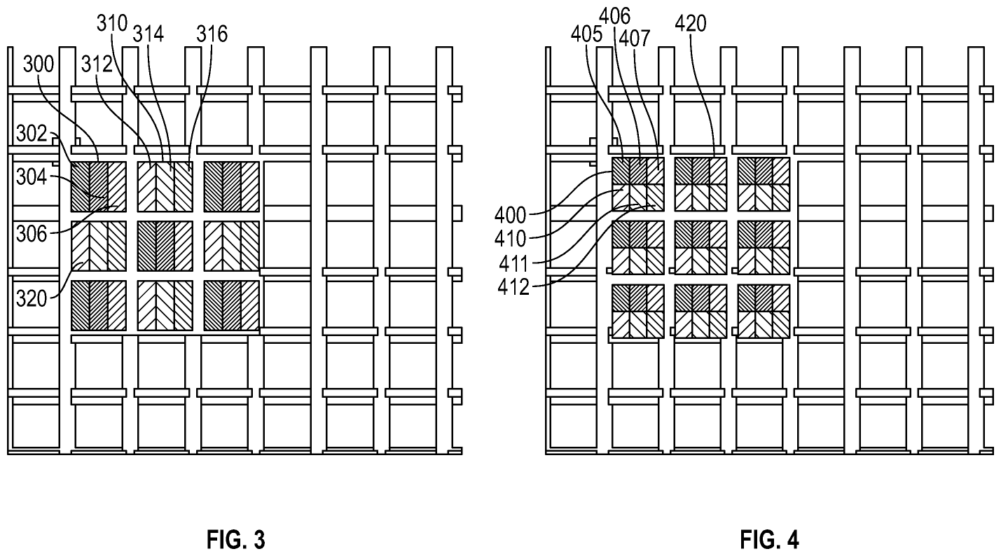

FIG. 3 shows a video display tile with primary pixel chips and secondary pixel chips. The primary pixel chips 300 are single chips that have Red parts 302, Green parts 304, and Blue parts 306. However, there are also secondary pixel chips 310, that display other colors beyond red green and blue, in the FIG. 3 embodiment Cyan 312, Magenta 314, and Yellow 316. Each two adjacent chips are alternate colors. The chip 300 is a red green blue chip and the neighboring chips 310 and 320 are cyan magenta yellow chips. In this way, each chip borders to another chip of an alternative color configuration.

This forms an LED video tile that has primary and secondary pixels. One set of primary pixels contains Red, Green, and Blue LEDs. Another set of secondary pixels contains Cyan, Magenta, and Yellow LEDs.

FIG. 4 shows a video display tile where every pixel is made up of multiple colors with pixels made up of multiple colors in a single pixel. The chips include Red, Green, Blue, but also include other colors like Cyan, Magenta, and Yellow. In this embodiment, each chip 400 includes a red part 405 green 406 and blue 407, and also includes a cyan 410, magenta 411 and yellow 412. Each chip such as 400, 420 is of the same color configuration, but each chip is capable of displaying multiple different colors. This forms an LED video display tile that has multi colored pixels made up of Red, Green, Blue, Cyan, Magenta, and Yellow LED's.

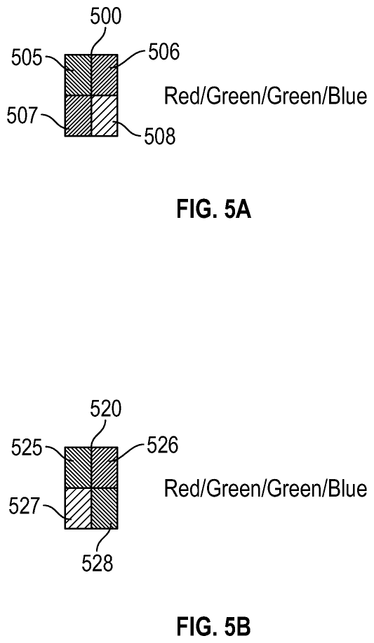

FIGS. 5-8 illustrate additional pixel LED color combinations according to embodiments that can produce advantages.

FIG. 5A shows a group where each pixel 500 has a red 505, a green 506, another green 507 and a blue 508 arrangements

Another pixel 520 in FIG. 5B has a red 525, green 526, blue 527, red 528 arrangement.

This forms an LED display that has colored pixels that include multiples of Red, Green, and Blue.

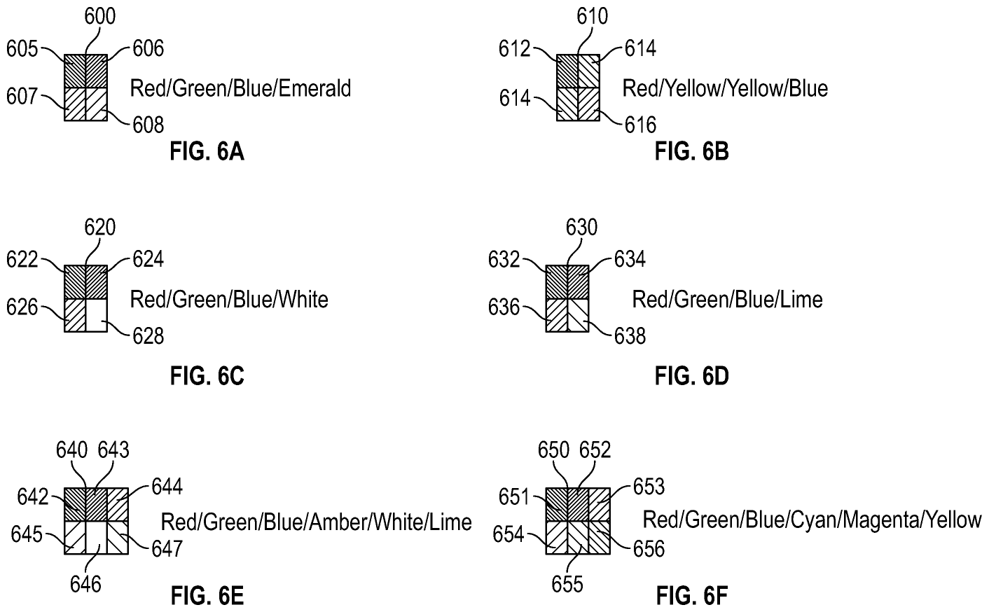

FIG. 6A shows a pixel chip formed of multiple different colors arranged into a rectangle. Each pixel chip such as 600 includes a different color configuration, and the pixel chips can be mixed or used homogeneously on an LED wall. The chip 600 includes a red portion 605, a green portion 606, a blue portion 607, and an emerald portion 608.

FIG. 6B shows an alternative pixel color configuration 610 which has pixels red 612, yellow 614, yellow 614 and blue 616.

FIG. 6C shows a pixel configuration 620 with red 622, green 624, blue 626 and white 628.

FIG. 6D shows a pixel configuration 630 with red 632 green 634 blue 636 and lime 638.

FIG. 6E shows a pixel configuration 640 which has six different colors: red 642, green 643, blue 644, amber 645, white 646 and lime 647.

FIG. 6F shows another six color pixel 650 having red 651 green 652 blue 653 cyan 654 magenta 655 and yellow 656.

This forms a display of colored pixels that contain LEDs that include Red, Green, Blue, as well as other colors.

The colored Pixels in this embodiment can also contain multiples of the same color.

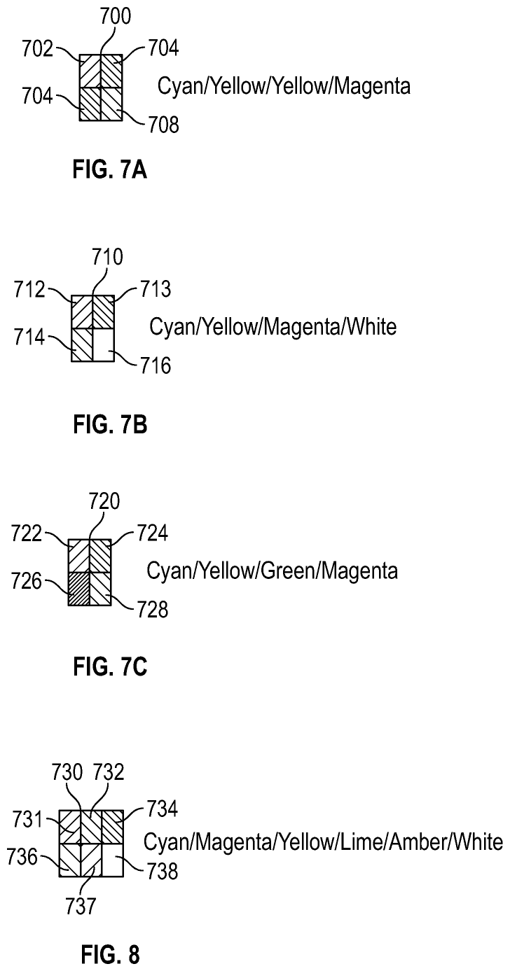

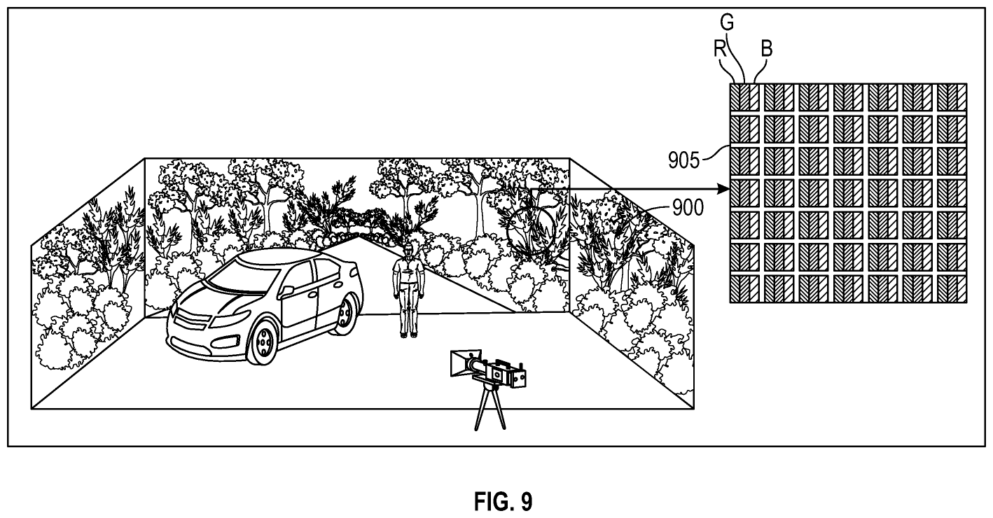

Additional pixel configurations are shown in FIGS. 7 and 8. These colored pixels may build on alternative colors cyan, magenta yellow, to include additional colors other than cyan, magenta and yellow.

FIG. 7A shows a pixel configuration 700 with cyan 702, yellow 704, yellow 706, and magenta 708.

FIG. 7B shows a pixel configuration 710 with cyan 712, yellow 713, magenta 714 and white 716.

FIG. 7C shows a pixel configuration 720 with cyan 722, yellow 724, green 726, and magenta 728.

FIG. 8 shows a subtractive pixel color 730 with cyan 731 magenta 732 yellow 734, lime 736, Amber 737, and white 738.

This forms Colored Pixels that contain LEDs other than red green and blue.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. An LED wall system, comprising a plurality of emitting pixels, each emitting pixel formed of at least one LED, the emitting pixels including at least one secondary color other than primary color pixels.

2. The LED wall system as in claim 1, further comprising red green and blue pixels as the primary color pixels, and also the at least one other secondary color pixel.

3. The LED wall system as in claim 2, wherein the at least one secondary color includes at least cyan magenta and yellow pixels.

4. The LED wall system as in claim 2, further comprising a camera, imaging the LED wall, along with secondary objects that are in front of, on the side of, and on top of the LED wall.

5. The system as in claim 1, wherein the primary color pixels include cyan, magenta, and yellow.

6. The system as in claim 1, wherein each emitting pixel is a single color LED.

7. The system as in claim 1, wherein each emitting pixel is a pixel chip that has multiple different colored parts, each colored part having a different color.

8. The system as in claim 7, wherein the pixel chips are arranged such that no two adjacent edges of pixel chips on front, side, top or bottom have the same color, and each chip borders to another chip of an alternative color configuration.

9. The system as in claim 2, wherein the at least one secondary color includes an emerald portion.

10. The system as in claim 2, wherein the at least one secondary color includes a yellow portion.

11. The system as in claim 2, wherein the at least one secondary color includes a lime portion.

12. The system as in claim 2, wherein the at least one secondary color includes a yellow portion.

13. An LED wall system, comprising a plurality of emitting pixels, each emitting pixel formed of multiple LED parts, including at least at multiple of a primary color.

14. The LED wall system as in claim 13, wherein the primary color includes red green and blue, and where there are multiple red emitting parts in a single pixel.

15. The LED wall system as in claim 13, wherein the primary colors include red, green and blue, and there are multiple Green parts in a single pixel.

16. An LED wall system, comprising a plurality of emitting pixels, each emitting pixel formed of multiple LEDs, including three primary color LED parts, and an additional primary color LED part including a color that is the same as one of the primary color LED parts.

17. The LED wall system as in claim 14, where the three primary color LED parts are red green and blue, and the additional primary color LED part is red.
